(19) United States
(12) Patent Application Publication
(10) Pub. No.: US 2011/0120549 A1
(43) Pub. Date: May 26, 2011

(54) THIN FILM SOLAR CELL AND MANUFACTURING METHOD THREOF, METHOD FOR INCREASING CARRIER MOBILITY IN SEMICONDUCTOR DEVICE, AND SEMICONDUCTOR DEVICE

(75) Inventor: Chin-Yao Tsai, Tainan County (TW)

(73) Assignee: AURIA SOLAR CO., LTD., Tainan (TW)

(21) Appl. No.: 12/951,069

(22) Filed: Nov. 22, 2010

(30) Foreign Application Priority Data
Nov. 20, 2009 (TW) 98139550
Nov. 20, 2009 (TW) 98139580

(51) Int. Cl. H01L 31/0256; H01L 31/18; H01L 21/265; H01L 29/772

(52) U.S. Cl. 136/256; 438/72; 438/514; 257/412; 257/E31.003; 257/E31.124; 257/E21.334; 257/E29.242

(57) ABSTRACT

A thin film solar cell including a substrate, a first conductive layer, a photovoltaic layer and a second conductive layer is provided. The first conductive layer is doped with boron atoms so as to have a texture structure. Isotope B¹⁰ doped in the first conductive layer accounts for more than 19.9% relative to the total boron atoms. The first conductive layer is disposed on the substrate. The photovoltaic layer is disposed on the first conductive layer. The second conductive layer is disposed on the photovoltaic layer. The present invention further provides a manufacturing method of a thin film solar cell, a method for increasing carrier mobility in a semiconductor device, and a semiconductor device.

### CROSS-REFERENCE TO RELATED APPLICATION

This application claims the priority benefits of Taiwan patent application serial no. 98139580, filed on Nov. 20, 2009, and application serial no. 98139550, filed on Nov. 20, 2009. The entirety of each of the above-mentioned patent applications is hereby incorporated by reference herein and made a part of specification.

### BACKGROUND OF THE INVENTION

1. Field of Invention

The present invention relates to a solar cell and a manufacturing method thereof, and more generally to a thin film solar cell with higher photoelectric conversion efficiency and a manufacturing method thereof.

2. Description of Related Art

Solar cells using monocrystalline silicon or polycrystalline silicon account for more than 90% in the solar cell market. However, these solar cells are made from silicon wafers of 150 μm to 350 μm thick, and the process cost thereof is higher. In addition, the raw materials of solar cells are silicon ingots with high quality. The silicon ingots face the shortage problem as the usage quantity thereof is increased significantly in recent years. Therefore, the thin film solar cell has been the new focus due to the advantages of low cost, easy for large-area production and simple module process, etc.

Generally speaking, in a conventional thin film solar cell, an electrode layer, a photovoltaic layer and another electrode layer are sequentially blanket-stacked on a substrate. During the process of stacking these layers, these layers are patterned by performing laser cutting processes, so as to form a plurality of sub cells connected in series. When a light enters the thin film solar cell from outside, free electron-hole pairs are generated in the photovoltaic layer by the solar energy, and the internal electric field formed by the PN junction makes electrons and holes respectively move toward two layers, so as to generate a storage state of electricity. Meanwhile, if a load circuit or an electronic device is connected, the electricity can be provided to drive the circuit or device.

However, the conventional thin film solar cell still has room for improving the whole photoelectric conversion efficiency thereof. Accordingly, more attention has been drawn on how to improve the photoelectric conversion efficiency and electrical performance of the conventional thin film solar cell so as to enhance the whole competitiveness of the products.

### SUMMARY OF THE INVENTION

The present invention provides a thin film solar cell, in which the light utilization rate is effectively enhanced and the recombination of electron-hole pairs on the surface is lowered, so as to achieve higher photoelectric conversion efficiency.

The present invention provides a manufacturing method to form the above-mentioned thin film solar cell.

The present invention further provides a method for increasing carrier mobility in a semiconductor device, in which a neutron treatment step is performed to the silicon substrate with boron dopants, so as to increase the carrier mobility and further enhance the performance of the device.

The prevent invention also provides a semiconductor device with higher carrier mobility.

The present invention provides a thin film solar cell including a substrate, a first conductive layer, a photovoltaic layer and a second conductive layer. The first conductive layer is doped with boron atoms so as to have a texture structure. Isotope B¹⁰ doped in the first conductive layer accounts for more than 19.9% relative to the total boron atoms. The first conductive layer is disposed on the substrate. The photovoltaic layer is disposed on the first conductive layer. The second conductive layer is disposed on the photovoltaic layer.

According to an embodiment of the present invention, the first conductive layer includes at least one of indium tin oxide (ITO), indium zinc oxide (IZO), indium tin zinc oxide (ITZO), zinc oxide, aluminium tin oxide (ATO), aluminium zinc oxide (AZO), cadmium indium oxide (CIO), cadmium zinc oxide (CZO), gallium zinc oxide (GZO) and fluorine tin oxide (FTO).

According to an embodiment of the present invention, the photovoltaic layer is a Group IV thin film, a III-V compound semiconductor thin film, a II-VI compound semiconductor thin film or an organic compound semiconductor thin film. In an embodiment, the Group IV thin film comprises at least one of an amorphous silicon (a-Si) thin film, a microcrystalline silicon (μc-Si) thin film, an amorphous silicon germanium (a-SiGe) thin film, a microcrystalline silicon germanium (μc-SiGe) thin film, an amorphous silicon carbide (a-SiC) thin film, a microcrystalline silicon carbide (μc-SiC) thin film, a tandem silicon thin film and a triple silicon thin film. In an embodiment, the III-V compound semiconductor thin film comprises gallium arsenide (GaAs) or indium gallium phosphide (InGaP). In an embodiment, the II-VI compound semiconductor thin film includes copper indium diselenide (CIS), copper indium gallium diselenide (CIGS), cadmium telluride (CdTe) or a combination thereof. In an embodiment, the organic compound semiconductor thin film includes a mixture of poly(3-hexylthiophene) (P3HT) and PCBM.

According to an embodiment of the present invention, the first conductive layer is a transparent conductive layer, and the second conductive layer includes at least one of a reflective layer and a transparent conductive layer.

The present invention provides a manufacturing method of a thin film solar cell. A substrate is provided. A first conductive layer is formed on the substrate. Boron atoms are doped in the first conductive layer so as to form a texture structure on a surface of the first conductive layer, wherein isotope B¹⁰ doped in the first conductive layer accounts for more than 19.9% relative to the total boron atoms. A photovoltaic layer is formed on the first conductive layer. A second conductive layer is formed on the photovoltaic layer.

According to an embodiment of the present invention, the method of doping the boron atoms includes an ion implantation process or a plasma doping process.

According to an embodiment of the present invention, the manufacturing method further includes performing a neutron treatment process to the first conductive layer doped with the boron atoms.

According to an embodiment of the present invention, the manufacturing method further includes performing a laser process to pattern the first conductive layer, so as to form a plurality of openings therein to expose the substrate.

According to an embodiment of the present invention, the manufacturing method further includes performing a laser process to pattern the photovoltaic layer, so as to form a plurality of openings therein to expose the first conductive layer.

According to an embodiment of the present invention, the manufacturing method further includes performing a laser process to pattern the second conductive layer, so as to form a plurality of openings therein to expose the first conductive layer.

According to an embodiment of the present invention, the method of forming the photovoltaic layer includes performing a radio frequency plasma enhanced chemical vapour deposition (RF PECVD) process, a vary high frequency plasma enhanced chemical vapour deposition (VHF CVD) process or a microwave plasma enhanced chemical vapour deposition (MW PECVD) process.

According to an embodiment of the present invention, the method of forming the second conductive layer includes forming at least one of a transparent conductive layer and a reflective layer on the photovoltaic layer, and the first conductive layer is a transparent conductive layer.

The present invention provides a method for increasing carrier mobility in a semiconductor device. A silicon substrate is provided. A boron doping step is performed to the silicon substrate. A neutron treatment step is performed to the silicon substrate.

According to an embodiment of the present invention, the material of the silicon substrate includes amorphous silicon or microcrystalline silicon.

According to an embodiment of the present invention, the boron doping step includes an boron ion implantation process.

According to an embodiment of the present invention, the neutron treatment step includes providing a neutron source, and directing neutrons generated from the neutron source to the silicon substrate.

According to an embodiment of the present invention, the neutron source includes a neutron generator.

According to an embodiment of the present invention, the boron doping step forms a doped region in the silicon substrate.

According to an embodiment of the present invention, the doped region is a source/drain region in a P-type metal oxide semiconductor (PMOS) transistor.

According to an embodiment of the present invention, the doped region is a source/drain region in a non-volatile memory device.

According to an embodiment of the present invention, the silicon substrate is a semiconductor layer in a solar cell.

According to an embodiment of the present invention, the silicon substrate is a P-type polysilicon gate.

The present invention further provides a semiconductor device including a silicon substrate and a boron doped region. The boron doped region is disposed in at least a portion of the silicon substrate, wherein neutrons are absorbed to the boron doped region.

According to an embodiment of the present invention, the material of the silicon substrate includes amorphous silicon or microcrystalline silicon.

According to an embodiment of the present invention, the boron doped region is a source/drain region in a P-type metal oxide semiconductor (PMOS) transistor.

According to an embodiment of the present invention, the boron doped region is a source/drain region in a non-volatile memory device.

According to an embodiment of the present invention, the silicon substrate is a semiconductor layer in a solar cell.

According to an embodiment of the present invention, the silicon substrate is a P-type polysilicon gate.

In view of the above, in the thin film solar cell of the present invention, the first conductive layer is doped with boron atoms so as to have a texture structure, and isotope B¹⁰ doped in the first conductive layer accounts for more than 19.9% relative to the total boron atoms. Therefore, the utilization rate of the light incident to the interior of the thin film solar cell is enhanced, the dangling bonds between the first conductive layer and the photovoltaic layer is decreased, and possibility of the recombination of electron-hole pairs on the surface is avoided. In addition, the present invention further provides a manufacturing method to form the above-mentioned thin film solar cell.

Moreover, in the present invention, a neutron treatment step is performed to the silicon substrate with boron dopants to increase carrier mobility, and thus, the operation speed of the device is enhanced and the performance of the device is further improved.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 schematically illustrates a cross-sectional view of a thin film solar cell according to an embodiment of the present invention.

FIGS. 2A to 2H schematically illustrate a process flow of manufacturing a thin film solar cell according to an embodiment of the present invention.

FIG. 3 schematically illustrates a cross-sectional view of a thin film solar cell according to another embodiment of the present invention.

FIG. 4 illustrates a process flow of a method for increasing carrier mobility in a semiconductor device according to an embodiment of the present invention.

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

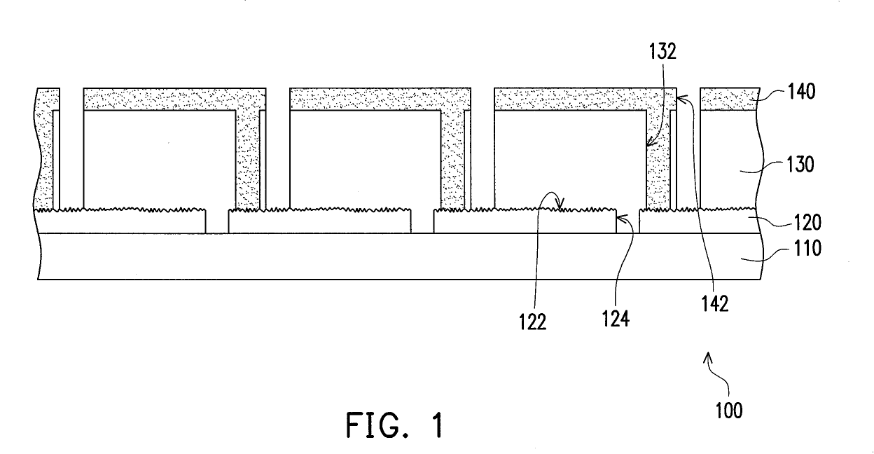

FIG. 1 schematically illustrates a cross-sectional view of a thin film solar cell according to an embodiment of the present invention. Referring to FIG. 1, in this embodiment, the thin film solar cell 100 includes a substrate 110, a first conductive layer 120, a photovoltaic layer 130 and a second conductive layer 140. In this embodiment, the substrate 110 can be a transparent substrate, such as a glass substrate.

The first conductive layer 120 is doped with boron atoms so as to have a texture structure 122, and isotope B¹⁰ doped in the first conductive layer 120 accounts for more than 19.9% relative to the total boron atoms. The first conductive layer 120 is disposed on the substrate 110, as shown in FIG. 1. In this embodiment, the first conductive layer 120 has a plurality of first openings 124 to expose a portion of the substrate 110. The first conductive layer 120 having the first openings 124 usually serves as front electrodes of a plurality of sub cells. In this embodiment, the first conductive layer 120 can be a transparent conductive layer, and the material thereof is at least one of indium tin oxide (ITO), indium zinc oxide (IZO), indium tin zinc oxide (ITZO), zinc oxide, aluminium tin oxide (ATO), aluminium zinc oxide (AZO), cadmium indium oxide (CIO), cadmium zinc oxide (CZO), gallium zinc oxide (GZO) and fluorine tin oxide (FTO), for example.

In details, the first conductive layer 120 is doped with boron atoms, so that the texture structure 122 as shown in FIG. 1 is formed on the surface 120a of the first conductive layer 120. In this embodiment, the texture structure 122 makes the light easy to refract or scatter, so as to enhance the efficiency of the light incident to the interior of the thin film solar cell 100. In addition, the texture structure 122 formed on the first conductive layer 120 by doping boron atoms can effectively increase the whole conductivity of the first conductive layer 120.

Referring to FIG. 1, the photovoltaic layer 130 is disposed on the first conductive layer 120, and a plurality of electron-hole pairs are generated as the photovoltaic layer 130 is illuminated. In this embodiment, the photovoltaic layer 130 has a plurality of second openings 132 to expose a portion of the first conductive layer 120. The photovoltaic layer 130 is physically connected to the substrate 110 through the first openings 124. The photovoltaic layer 130 having the second openings 132 usually serves as a photoelectric conversion layer (or light absorption layer) in the plurality of sub cells connected in series. In this embodiment, the photovoltaic layer 130 can be a Group IV thin film, a III-V compound semiconductor thin film, a II-VI compound semiconductor thin film or an organic compound semiconductor thin film. In details, the Group IV thin film includes at least one of an amorphous silicon (a-Si) thin film, a microcrystalline silicon (μc-Si) thin film, an amorphous silicon germanium (a-SiGe) thin film, a microcrystalline silicon germanium (μc-SiGe) thin film, an amorphous silicon carbide (a-SiC) thin film, a microcrystalline silicon carbide (μc-SiC) thin film, a tandem silicon thin film and a triple silicon thin film, for example. The III-V compound semiconductor thin film includes a gallium arsenide (GaAs) thin film, an indium gallium phosphide (InGaP) thin film or a combination thereof, for example. The II-VI compound semiconductor thin film can be a copper indium diselenide (CIS) thin film, a copper indium gallium diselenide (CIGS) thin film, a cadmium telluride (CdTe) thin film or a combination thereof, for example. The organic compound semiconductor thin film includes a mixture of poly(3-hexylthiophene) (P3HT) and PCBM, for example.

That is, the thin film solar cell 100 can at least include the film layer structure of an amorphous silicon thin film solar cell, a microcrystalline silicon thin film solar cell, a tandem thin film solar cell, a triple thin film solar cell, a CIS thin film solar cell, a CIGS thin film solar cell, a GdTe thin film solar cell or an organic thin film solar cell. In other words, the photovoltaic layer 130 of this embodiment is provided only for illustration purposes, and can be decided according to the users' requirements. The thin film solar cell 100 can also include the film layer structure of another suitable thin film solar cell. In an embodiment, when the photovoltaic layer 130 of the thin film solar cell 100 is a tandem structure, it can be a stacked layer of amorphous silicon and microcrystalline silicon.

In this embodiment, a plurality of dangling bonds are present on the contact surface between the first conductive layer 120 and the photovoltaic layer 130. Besides, isotope B¹⁰ doped in the first conductive layer 120 of this embodiments accounts for more than 19.9% relative to the total boron atoms, and neutrons are absorbed to isotope B¹⁰. Accordingly, after a neutron treatment process is performed to the first conductive layer 120, the amount of the dangling bonds between the first conductive layer 120 and the photovoltaic layer 130 can be effectively decreased. Therefore, the possibility of the recombination of electron-hole pairs on the surface of the photovoltaic layer 130 is lowered, and the electrical performance and photoelectric conversion efficiency of the thin film solar cell 100 are further improved.

In other words, in this embodiment, the texture structure 120 is formed mainly by depositing boron atoms on the first conductive layer 120, and thus, the efficiency of the light incident to the thin film solar cell 100 is enhanced, the whole conductivity of the first conductive layer 120 is increased, and the whole electrical performance of the thin film solar cell 100 is further improved. Meanwhile, isotope B¹⁰ doped in the first conductive layer 120 accounts for more than 19.9% relative to the total boron atoms, so that after a neutron treatment is performed to the first conductive layer 120, the dangling bonds between the first conductive layer 120 and the photovoltaic layer 130 is reduced, and the electrical performance and photoelectric conversion efficiency of the thin film solar cell 100 is further improved.

Referring again to FIG. 1, the second conductive layer 140 is disposed on the photovoltaic layer 130. The second conductive layer 140 has a plurality of third openings 142 to expose a portion of the first conductive layer 120 and a portion of the side surface of the photovoltaic layer 130. The second conductive layer 140 is physically connected to the first conductive layer 120 through the second openings 132. Further, the second conductive layer 142 can include the material of the above-mentioned transparent conductive layer, and the details are not iterated herein. In this embodiment, the second conductive layer 140 can further include a reflective layer disposed on the transparent conductive layer.

In view of the above, the thin film solar cell 100 is irradiated by light (not shown) to generate electron-hole pairs. The first conductive layer 120 of the thin film solar cell 100 is doped with boron atoms so as to form the texture structure 122, and isotope B¹⁰ doped in the first conductive layer 120 accounts for more than 19.9% relative to the total boron atoms. Accordingly, the efficiency of the light incident to the thin film solar cell 100 is enhanced, the whole conductivity of the first conductive layer 120 is increased. Further, a neutron treatment process can be performed to the first conductive layer 120 to lower the dangling bonds between the first conductive layer 120 and the photovoltaic layer 130, so as to improve the photoelectric efficiency of the thin film solar cell 100.

In addition, the present invention also provides a manufacturing method to form the above-mentioned thin film solar cell 100, which is described in the following.

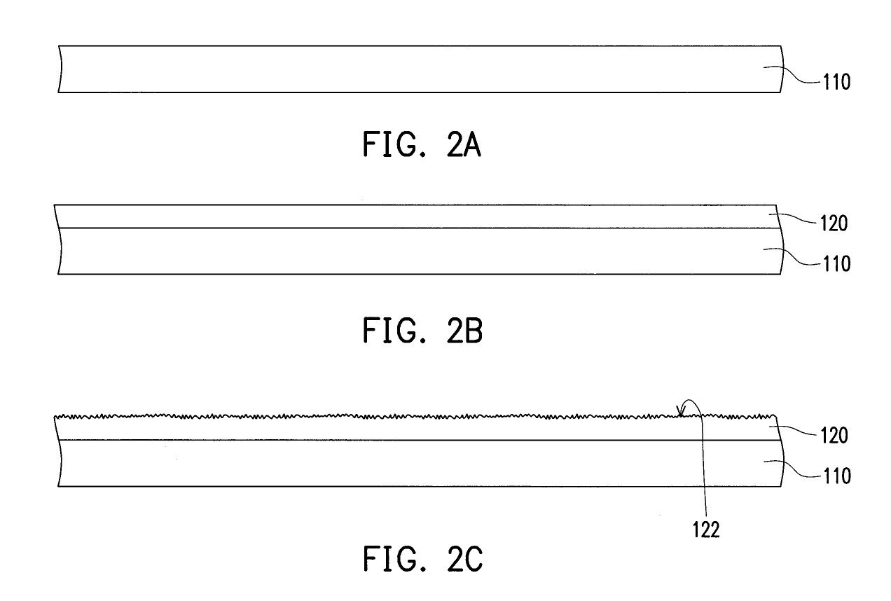

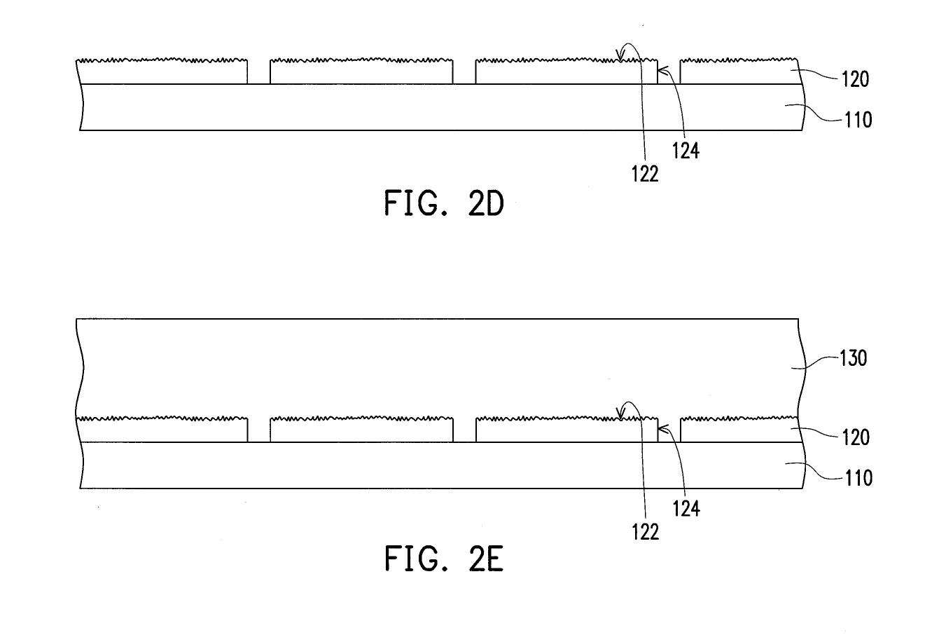

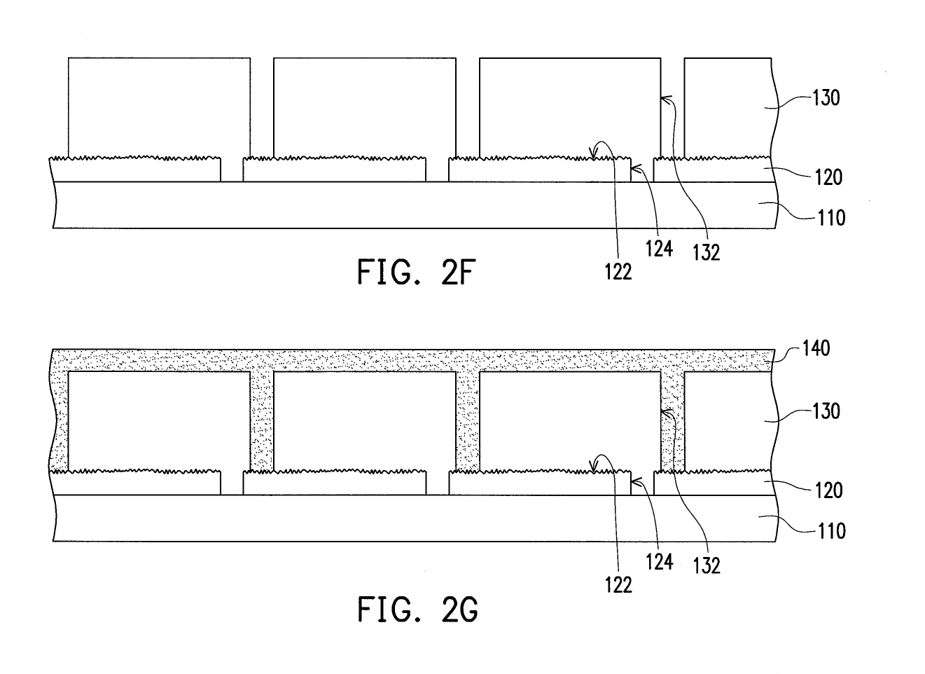

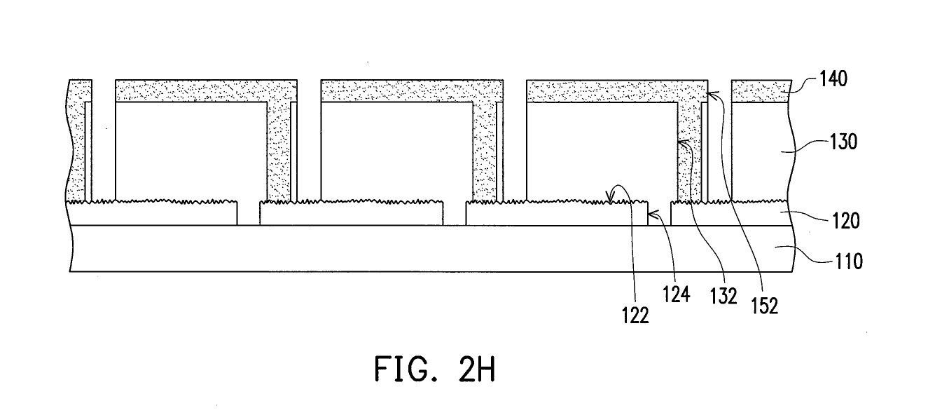

FIGS. 2A to 2H schematically illustrate a process flow of manufacturing a thin film solar cell according to an embodiment of the present invention. Referring to FIG. 2A, the above-mentioned substrate 110 is provided. The substrate 110 can be a transparent substrate, such as a glass substrate.

Referring to FIG. 2B, the above-mentioned first conductive layer 120 is formed on the substrate 110. The first conductive layer 120 includes the material of the above-mentioned transparent conductive layer, and the forming method thereof is by performing a sputtering process, a metal organic chemical vapour deposition (MOCVD) process or an evaporation process, for example.

Thereafter, boron atoms are doped in the first conductive layer 120, so as to form a texture structure 122 on the surface 120a of the first conductive layer 120, and isotope B¹⁰ doped in the first conductive layer 120 accounts for more than 19.9% relative to the total boron atoms, as shown in FIG. 2C. In this embodiment, the method of doping the boron atoms in the first conductive layer 120 is by performing an ion implantation process or a plasma doping process, for example.

Referring to FIG. 2D, the above-mentioned first openings 124 are formed in the first conductive layer 120 to expose a portion of the substrate 110. Accordingly, front electrodes of a plurality of sub cells connected in series are formed. In this embodiment, the method of forming the first openings 124 is by patterning the first conductive layer 120 with a laser process, for example.

Referring to FIG. 2E, the above-mentioned photovoltaic layer 130 is formed on the first conductive layer 120. In this embodiment, the method of forming the photovoltaic layer 130 is by sequentially forming a plurality of semiconductor stacked layers. Accordingly, a photoelectric conversion layer as a tandem structure is formed. In details, the method of forming the photovoltaic layer 130 is by performing a radio frequency plasma enhanced chemical vapour deposition (RF PECVD) process, a vary high frequency plasma enhanced chemical vapour deposition (VHF CVD) process or a microwave plasma enhanced chemical vapour deposition (MW PECVD) process, for example. The above-mentioned forming method of the photovoltaic layer 130 is provided only for illustration purposes, and is not construed as limiting the present invention. The forming method of the photovoltaic layer 130 can be adjusted depending on the film layer design (e.g. the structure of the above-mentioned Group IV thin film or II-VI compound semiconductor thin film) of the photovoltaic layer 130. Further, the deposition thickness of the photovoltaic layer 130 can be decided according to the users' requirements.

Referring to FIG. 2F, the above-mentioned second openings 132 are formed in the photovoltaic layer 130 to expose a portion of the first conductive layer 120. The photovoltaic layer 130 is physically connected to the substrate 110 through the first openings 124. In this embodiment, the method of forming the second openings 132 is by patterning the photovoltaic layer 130 with a laser process, for example.

Referring to FIG. 2G, the above-mentioned second conductive layer 140 is formed on the photovoltaic layer 130 and in the second openings 132, and covers the portion of the first conductive layer 120 exposed by the second openings 132. In this embodiment, the second conductive layer 140 and the first conductive layer 130 have the same forming method. That is, the method of forming the second conductive layer 140 is by performing the above-mentioned sputtering process, MOCVD process, or evaporation process, for example. The material of the second conductive layer 140 is the material of the above-mentioned transparent conductive layer, and the details are not iterated herein.

Referring to FIG. 2H, the above-mentioned third openings 142 are formed in the second conductive layer 140 to expose a portion of the first conductive layer 120 and a portion of the side surface of the photovoltaic layer 130. The second conductive layer 140 is physically connected to the first conductive layer 120 through the second openings 132. In this embodiment, the method of forming the third openings 142 is by patterning the second conductive layer 140 with a laser process, for example. Accordingly, back electrodes of the plurality of sub cells connected in series are formed. The manufacturing method of the thin film solar cell 100 is thus completed.

In this embodiment, the second conductive layer 140 is a stacked structure of a transparent conductive layer and a reflective layer, and the first conductive layer 120 is a transparent conductive layer, for example. Herein, a transparent conductive layer is formed on the photovoltaic layer 130, and a reflective layer is formed on the transparent conductive layer, so as to form the second conductive layer 140. Accordingly, a thin film solar cell with one-sided illumination is formed.

It is noted that a neutron treatment process can be performed to the first conductive layer 120 in any step after the photovoltaic layer 130 is formed on the first conductive layer 120, so as to reduce the dangling bonds present between the first conductive layer 120 and the photovoltaic layer 130, and further improve the photoelectric conversion efficiency of the thin film solar cell 100.

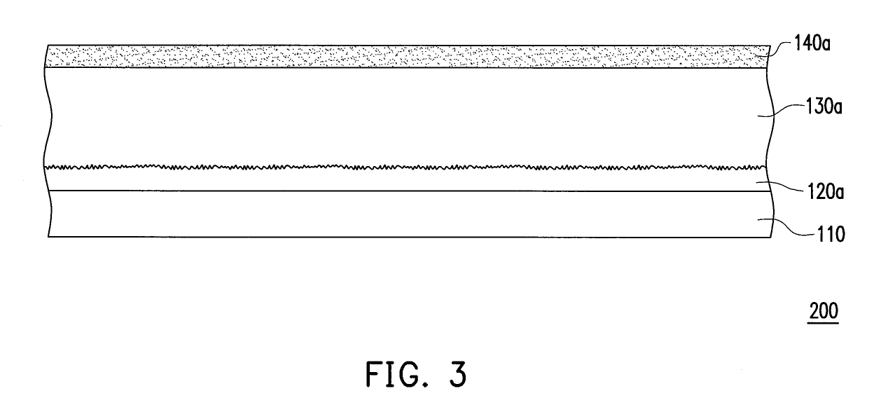

In addition, another thin film solar cell 200 is provided, as shown in FIG. 3. FIG. 3 schematically illustrates a cross-sectional view of a thin film solar cell according to another embodiment of the present invention. Referring to FIG. 1 and FIG. 3, the thin film solar cell 200 is similar to the thin film solar cell 100, and the difference between them lies in that the first conductive layer 120a, the photovoltaic layer 130a and the second conductive layer 140a of the thin film solar cell 200 do not have the above-mentioned openings. That is, the thin film solar cell 200 is designed as a single sub cell only, not a plurality of sub cells connected in series as shown in FIG. 1. Moreover, the thin film solar cell 200 also has a texture structure formed by doping boron atoms, and isotope B¹⁰ doped in the first conductive layer accounts for more than 19.9% relative to the total boron atoms. Therefore, the thin film solar cell 200 also has the advantages of the above-mentioned thin film solar cell 100, and the details are not iterated herein.

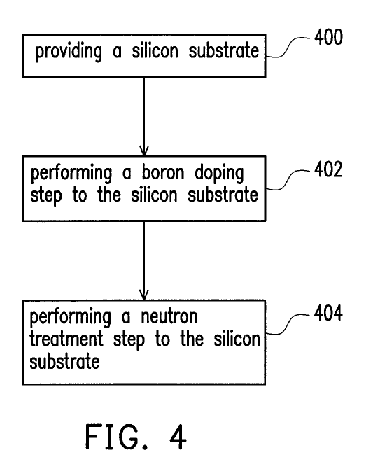

FIG. 4 illustrates a process flow of a method for increasing carrier mobility in a semiconductor device according to an embodiment of the present invention. Referring to FIG. 4, a silicon substrate is provided in the step 400. The material of the silicon substrate is amorphous silicon or microcrystalline silicon, for example. The silicone substrate can be a substrate of a semiconductor device, a semiconductor layer in a solar cell, or a silicon-containing substrate.

Thereafter, a boron doping step is performed to the silicon substrate in the step 402. The boron doping step is a boron ion implantation process to implant boron ions in the silicon substrate, for example. In addition, a heating process can be optionally performed after the boron doping step, so as to further diffuse the boron ions in the silicon substrate. In an embodiment, a doped region is formed in the silicon substrate after the boron doping step. Specifically, when the silicon substrate is a substrate of a P-type metal oxide semiconductor (PMOS) transistor, a P-type source/drain region is formed in the silicon substrate in the boron doping step. When the silicon substrate is a substrate of a non-volatile memory device, a source/drain region is formed in the silicon substrate in the boron doping step. In another embodiment, the boron doping step can be performed to the whole silicon substrate. For example, a P-type semiconductor layer in a solar cell can be formed by the boron doping step. Further, in another embodiment, the silicon substrate can be a P-type polysilicon gate in a MOS transistor or a memory device.

Afterwards, a neutron treatment step is performed to the silicon substrate in the step 404, so that neutrons are absorbed to the boron dopants in the silicon substrate. In details, when the neutrons are absorbed to the boron dopants, the dangling bonds are saturated to increase carrier mobility and further enhance the operation speed of the device. The neutron treatment step includes providing a neutron source, and then directing neutrons generated from the neutron source to the silicon substrate. In an embodiment, the neutron source is a neutron generator, for example.

In summary, the thin film solar cell of the present invention and the manufacturing method thereof at least have the following advantages. First, boron atoms are disposed on the first conductive layer so as to form a texture structure. Therefore, the utilization rate of the light incident to the interior of the thin film solar cell is enhanced, the whole conductivity of the first conductive layer is increased, and the whole electrical performance of the thin film solar cell is further improved. In addition, isotope B¹⁰ doped in the first conductive layer accounts for more than 19.9% relative to the total boron atoms, and after a neutron treatment is performed to the first conductive layer, the dangling bonds between the first conductive layer and the photovoltaic layer are reduced, and the electrical performance and whole photoelectric conversion efficiency of the thin film solar cell are further improved.

Besides, in the manufacturing method of the present invention, a simple process step can be performed to form the above-mentioned texture structure, so as to form the above-mentioned thin film solar cell. Moreover, by performing a neutron treatment step to the first conductive layer, the dangling bonds between the first conductive layer and the photovoltaic layer are reduced to further improve the whole photoelectric conversion efficiency of the thin film solar cell.

Also, in the present invention, a neutron treatment step can be performed to the silicon substrate with boron dopants, so as to saturate the dangling bonds. Accordingly, the operation speed of the device is enhanced and the performance of the device is further improved.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A thin film solar cell, comprising:
a substrate;
a first conductive layer, doped with boron atoms so as to have a texture structure, wherein isotope B¹⁰ doped in the first conductive layer accounts for more than 19.9% relative to the total boron atoms, and the first conductive layer is disposed on the substrate;
a photovoltaic layer, disposed on the first conductive layer; and
a second conductive layer, disposed on the photovoltaic layer.

2. The thin film solar cell of claim 1, wherein the first conductive layer comprises at least one of indium tin oxide (ITO), indium zinc oxide (IZO), indium tin zinc oxide (ITZO), zinc oxide, aluminium tin oxide (ATO), aluminium zinc oxide (AZO), cadmium indium oxide (CIO), cadmium zinc oxide (CZO), gallium zinc oxide (GZO) and fluorine tin oxide (FTO).

3. The thin film solar cell of claim 1, wherein the photovoltaic layer is a Group IV thin film, a III-V compound semiconductor thin film, a II-VI compound semiconductor thin film or an organic compound semiconductor thin film.

4. The thin film solar cell of claim 3, wherein the Group IV thin film comprises at least one of an amorphous silicon (a-Si) thin film, a microcrystalline silicon (μc-Si) thin film, an amorphous silicon germanium (a-SiGe) thin film, a microcrystalline silicon germanium (μc-SiGe) thin film, an amorphous silicon carbide (a-SiC) thin film, a microcrystalline silicon carbide (μc-SiC) thin film, a tandem silicon thin film and a triple silicon thin film.

5. The thin film solar cell of claim 3, wherein the III-V compound semiconductor thin film comprises gallium arsenide (GaAs) or indium gallium phosphide (InGaP).

6. The thin film solar cell of claim 1, wherein the first conductive layer is a transparent conductive layer, and the second conductive layer comprises at least one of a reflective layer and a transparent conductive layer.

7. A manufacturing method of a thin film solar cell, comprising:
providing a substrate;
forming a first conductive layer on the substrate;
doping boron atoms in the first conductive layer so as to form a texture structure on a surface of the first conductive layer, wherein isotope B¹⁰ doped in the first conductive layer accounts for more than 19.9% relative to the total boron atoms;
forming a photovoltaic layer on the first conductive layer; and
forming a second conductive layer on the photovoltaic layer.

8. The manufacturing method of claim 7, wherein a method of doping the boron atoms comprises an ion implantation process or a plasma doping process.

9. The manufacturing method of claim 7, further comprising performing a neutron treatment process to the first conductive layer doped with the boron atoms.

10. The manufacturing method of claim 7, wherein a method of forming the second conductive layer comprises forming at least one of a transparent conductive layer and a reflective layer on the photovoltaic layer, and wherein the first conductive layer is a transparent conductive layer.

11. A method for increasing carrier mobility in a semiconductor device, comprising:
providing a silicon substrate;
performing a boron doping step to the silicon substrate; and
performing a neutron treatment step to the silicon substrate.

12. The method of claim 11, wherein a material of the silicon substrate comprises amorphous silicon or microcrystalline silicon.

13. The method of claim 11, wherein the boron doping step comprises an boron ion implantation process.

14. The method of claim 11, wherein the neutron treatment step comprises:
providing a neutron source; and
directing neutrons generated from the neutron source to the silicon substrate.

15. The method of claim 14, wherein the neutron source comprises a neutron generator.

16. The method of claim 11, wherein the boron doping step forms a doped region in the silicon substrate.

17. The method of claim 16, wherein the doped region is a source/drain region in a P-type metal oxide semiconductor (PMOS) transistor.

18. The method of claim 16, wherein the doped region is a source/drain region in a non-volatile memory device.

19. The method of claim 11, wherein the silicon substrate is a semiconductor layer in a solar cell.

20. The method of claim 11, wherein the silicon substrate is a P-type polysilicon gate.

21. A semiconductor device, comprising:
a silicon substrate; and
a boron doped region, disposed in at least a portion of the silicon substrate, wherein neutrons are absorbed to the boron doped region.

22. The semiconductor device of claim 21, wherein a material of the silicon substrate comprises amorphous silicon or microcrystalline silicon.

23. The semiconductor device of claim 21, wherein the boron doped region is a source/drain region in a P-type metal oxide semiconductor (PMOS) transistor.

24. The semiconductor device of claim 21, wherein the boron doped region is a source/drain region in a non-volatile memory device.

25. The semiconductor device of claim 21, wherein the silicon substrate is a semiconductor layer in a solar cell.

26. The semiconductor device of claim 21, wherein the silicon substrate is a P-type polysilicon gate.
